(19) United States
(12) Patent Application Publication
(10) Pub. No.: US 2008/0209931 A1
(43) Pub. Date: Sep. 4, 2008

(54) DATA CENTERS

(76) Inventor: Jason Stevens, Mornington (AU)

Correspondence Address: DARBY & DARBY P.C., P.O. BOX 770, Church Street Station, New York, NY, 10008-0770, US

(21) Appl. No.: 11/734,835

(22) Filed: Apr. 13, 2007

(30) Foreign Application Priority Data
Mar. 1, 2007 (GB) 0703995.1

(51) Int. Cl. H05K 7/20; F28F 1/00

(52) U.S. Cl. 62/259.2; 165/185

(57) ABSTRACT

The invention is concerned with new approaches to cooling processing equipment in data centers. A cooling system is described herein that is suitable for cooling processing equipment in data centers. The cooling system includes a vertical conduit carrying a cooling liquid and an array of elongate heat conducting elements, such as heat pipes, extending laterally outwardly from the conduit. An inner end portion of each heat conducting element is in thermal contact with cooling liquid flowing in the conduit and an outer end portion of each heat conducting element is adapted for conductive thermal contact with at least one heat producing electronic component.

### FIELD OF THE INVENTION

The present invention relates to data center technology. It is particularly concerned with new approaches to cooling processing equipment in data centers.

### BACKGROUND

Conventional data centers occupy large rooms with closely controlled environmental conditions. The data storage and processing equipment generally takes the form of servers, which are mounted in standard (e.g. 19 inch) rack cabinets, the cabinets being arranged in a series of rows in the room. The rack mounted servers must be cooled to remove the excess heat generated by their processors and other components, so complex air conditioning systems are required to maintain the desired temperature and humidity in the room. These air conditioning units have large power demands, to the extent that in some cases it is the capacity of local electricity grids that place limits on the maximum size of data centers.

There is an ever increasing demand for data storage and processing capacity. Particularly in recent years a massive growth in Internet services including streaming of high quality video content has resulted in a corresponding massive growth in the capacity and performance demands placed on data centers serving this content. The volume of corporate data that must be securely stored in data warehouses also continues to grow rapidly.

Providers of data center technology have responded by increasing processor and data storage density where possible. However, despite improvements in processor efficiency, increases in processing power are inevitably accompanied by increases in the heat generated by the servers' processors and limits are quickly reached beyond which it becomes difficult to effectively cool the processors using conventional approaches because of the load that is put on the air conditioning systems and subsequent costs.

In effect, limitations in the ability to cool processors place serious physical limits on the capacity of data centers, which if exceeded can cause problems including hot servers potentially leading to malfunctions, reduced mean time before failure (MTBF) and unexpected thermal shutdowns.

These cooling problems associated with conventional data centers are exacerbated by the approach that is normally taken to providing redundancy in the system to cater for hardware failures, with most components in the data center being at least duplicated (a so called “N+1” approach). This approach multiplies the number of servers required in a data center for any given storage/processing capacity, with a corresponding multiplication of the cooling effort that is necessary. Moreover, this duplicated equipment is sized to account for peak loads, which are generally experienced very infrequently, meaning much of the capacity of the system remains idle whilst still requiring cooling effort. The increasing popularity of virtualisation of servers, which increases loads on processors, can only make things worse.

More recently, providers of data center equipment have proposed liquid cooling as an alternative to the conventional wholly air-cooled approach. Chilled water (or another liquid cooling medium) is piped around the cabinets and/or racks in which the servers are mounted to remove heat more efficiently (the thermal capacity of water being much greater than that of air). However, to bring the cooling liquid close to the processors (the components that produce the most heat), in order to minimise the reliance on convection to transport heat from the processors to the cooling liquid, intricate pipe work is needed, complicating server maintenance. The potentially very serious risk of leaks and condensation causing electrical shorts must also be considered.

Another approach that has been proposed recently by Hewlett Packard is to spray a fine mist of non-conductive cooling fluid over the server racks to lower the air temperature around the servers.

### SUMMARY OF INVENTION

In some of its aspects the present invention is generally concerned with a new approach to cooling electronic equipment and finds particular application in cooling heat producing components in data center apparatus, such as (electrical or optical) processors (sometimes referred to as ‘CPU’s), RAM, other microchips, hard drives, etc. The general proposition is to use a conducting element to conduct heat from a heat producing electronic component (e.g. a semiconductor device) to a liquid (e.g. water) column spaced from the heat producing component. Multiple heat conducting elements can be used to conduct heat from multiple heat producing components to a single liquid column.

In a first aspect, there is provided a cooling system for electronic equipment comprising a plurality of heat producing electronic components, the cooling system comprising:

a conduit carrying a cooling liquid; and

a plurality of elongate heat conducting elements extending outwardly from the conduit;

an inner end portion of each heat conducting element being in thermal contact with cooling liquid in the conduit and an outer end portion of each heat conducting element being adapted for conductive thermal contact with at least one heat producing electronic component.

Adopting this approach, heat can be efficiently transported away from the heat producing component by the heat conducting element to the cooling liquid without the need to pipe the cooling liquid individually to the heat producing components. Where this approach is adopted in a data center environment, as the cooling liquid can subsequently be used to transport the heat away from the vicinity of the data center equipment, the air conditioning requirements for the data center can be significantly less than conventional installations.

The cooling liquid may be water. In some embodiments the water (or other cooling liquid) flows through the conduit past or across the inner end portions of the heat conductors. For instance, the cooling liquid may be gravity fed and/or pumped through the conduit.

The inner end portions of the heat conducting elements may extend inside the conduit so that they are immersed in the cooling liquid. In some embodiments, the inner end portions of the heat conducting elements extend across substantially the whole width of the conduit to maximise the length of the inner end portion that is immersed in the cooling liquid. The inner ends of the heat conducting elements may be (thermally) connected to heat sinks over which the cooling liquid flows inside the conduit, the heat sinks having a larger surface area than the heat pipe(s) they are connected to. This can increase the rate at which heat is transferred to the cooling liquid.

The conduit may be elongate and in some embodiments is oriented to be vertical with the heat conductors extending generally laterally therefrom. The paths followed by the heat conducting elements need not be straight. They may, for example, be angled and/or curved.

In some embodiments the heat conducting elements, whilst still extending generally laterally, may slope upwards towards their inner ends, either along the whole their length or part of their length (e.g. an inner part, such as an inner half, the outer part being generally horizontal).

The heat conductors may protrude from more than one side of the conduit. For instance, they may protrude from two opposite sides of the conduit.

A plurality of heat conductors may protrude from one or more sides of the conduit, the conductors on any one side of the conduit being spaced from one another along the length and/or width of the conduit.

In some embodiments there may be several hundred or more heat conductors protruding to one or more sides of the cooling liquid conduit. For instance there may be 200 or more, 300 or more, 400 or more, 500 or more or even 1,000 or more heat conductors protruding from the conduit.

One or more of the heat conductors may be adapted to each be in thermal contact with more than one heat producing electronic component.

Two or more heat conducting elements may be adapted to be in thermal contact with the same heat producing component.

The heat conducting elements may be in conductive thermal contact with the heat producing elements via physical contact with a heat sink that is in physical contact with the heat producing component.

The heat conducting elements may be metallic. In some embodiments, however, they may be non-metallic.

The heat conducting elements may be elongate rods. In some embodiments the heat conducting elements are hollow and may, for instance, be heat pipes, which are more efficient at transferring heat than solid conductors.

In some embodiments at least some of the heat conducting elements (e.g. heat pipes) are adapted to provide a physical support for the heat producing electronic components. In this way the cooling system can serve additionally as a support structure for the electronic components e.g. of a data center.

Particularly in the case where the heat pipe conductors alone are not sufficiently robust to support the full weight of the electronic components (and other structure associated with them), one or more solid heat conducting elements may be provided in addition to the heat pipe(s). For instance, the heat conducting structure may include alternate heat pipes and solid conductors.

Additionally, or alternatively, other support members or structure may be provided for the electronic components to reduce (or substantially remove all of) the load on the heat pipes or other conducting elements.

The electronic equipment for which the cooling system is provided may be data center equipment.

The heat producing components that are cooled may be semiconductor components, such as processors (e.g. CPUs, graphic processors, optical processors), memory chips, server fabric switches, solid state storage devices or other microchips, or other components such as magnetic, optical or combination storage devices (e.g. hard drives).

In a second aspect, there is provided electronic apparatus comprising:

a plurality of heat producing electronic components; and

a cooling system for the electronic components as set forth in the first aspect above.

In a third aspect, there is provided a data center processor stack comprising:

a plurality of heat producing electronic components;

a support structure for the electronic components; and

a cooling system for the electronic components, the cooling system comprising:
i. a conduit carrying a cooling liquid; and
ii. a plurality of elongate heat conducting elements extending outwardly from the conduit;
iii. an inner end portion of each heat conducting element being in thermal contact with cooling liquid in the conduit and an outer end portion of each heat conducting element being adapted for conductive thermal contact with at least one of said electronic components.

The heat producing electronic components may be processors, storage units, switches (e.g. fabric switches) or a combination of any two more of these types of component.

The cooling system of this aspect may include any one or more of the features set out above in the context of the first aspect of the invention. For example, the heat conducting elements (which in some embodiments are heat pipes) may serve as part of the support structure for the processors. This can provide a very compact overall structure for the processor stack, enabling higher density of processors than is possible with conventional rack-based data centers.

The data center processor stack of the fourth aspect may be modular, the processors being selectively detachable from the support structure. They may for instance be selectively dismountable from the heat conducting element(s) on which they are mounted, in the case where these elements serve as the support structure.

Each processor may be mounted on a mother board. The mother board can provide connections from the processor to a power source. The mother board may be adapted for mounting other components, for example one or more memory chips (e.g. RAM), one or more connectors to hard disk drives, a power switch, etc.

In some embodiments, two or more processors are mounted together on a single mother board. For instance, each motherboard may have 4 (or more) processors mounted thereon.

The mother board, and the processor(s) and any other components mounted on it may be a removable module. In some embodiments, when the removable mother board module is mounted on the data center processor stack it is brought into contact with power and/or data connectors on the stack (e.g. on the cooling liquid conduit of the cooling system) to make power and/or data connections with the mother board and components mounted on it.

In some embodiments the data center processor stack comprises a plurality of nodes where a modular component can be installed. Each node may comprise one or more of the heat conducting elements. The heat conducting element(s) at each node may provide support for the modular component mounted at the node. One example of the modular component is the removable mother board module referred to above. Another example of a modular component is a storage module comprising one or more hard disk drives or other storage units. Another example of a modular component is a switch module comprising one or more fabric switches.

The data center processor stack may comprise an array of nodes on one side, two sides (e.g. two opposite sides) or more than two sides of the cooling liquid conduit. The or each may comprise a plurality of nodes arranged side-by-side, stacked one on top of the other or both side-by-side and stacked one on top of the other.

The (or each) array of nodes may comprise 5 or 10 or more nodes across the width of the stack. The (or each) array of nodes may comprise 10 or 15 or more nodes up the height of the stack. Two such arrays may be provided on opposite sides on a central cooling liquid conduit.

In some embodiments, some of the nodes (processing nodes) in the array will have processing (motherboard) modules mounted on them, other nodes (storage nodes) will have storage modules mounted on them and still other nodes (switch nodes) will have switch modules mounted on them. The processing nodes, storage nodes and switch nodes may be intermingled to more evenly distribute the generation of heat across the stack, for example alternate rows in the (or each) array of nodes may be processing and storage nodes respectively or processing and switch nodes respectively.

The ratio between the number of storage nodes, the number of processing nodes and the number of switch nodes can be selected to best match the intended application. In some embodiments data center processor stack might include only processor nodes or only storage nodes or only switch nodes.

In some embodiments, the data center processing stack is dimensioned to occupy the same floor space as a conventional rack (e.g. a 19 inch, 42RU rack).

In some embodiments, to supplement the cooling effect of the cooling system, a fan is used to generate a flow of air over the processors and/or motherboards of other components where present.

In a fourth aspect, there is provided a data center comprising a plurality of data center processor stacks in accordance with the third aspect above.

The processor stacks of the data center of this fourth aspect may be connected to a common data network in a conventional fashion. The data network may be connected to the Internet.

The processor stacks may have a shared power supply. In some embodiments the processor stacks of the data center are powered by UPS's and/or PSU's with redundancy built into the power supply system. The power supplies may be located away from the processor stacks in an isolated area with conventional ventilation and air conditioning arrangements so that the heat generated by the power supplies does not impact on the processor stacks.

The cooling systems of a plurality (in some embodiments all) of the processor stacks in the data center may have a shared cooling liquid supply circuit (i.e. one or more components of the circuit may be shared). Alternatively, each cooling system may have its own supply circuit.

The cooling liquid supply circuit (whether shared or not) may include a cooling liquid reservoir.

Cooling liquid may be pumped and/or gravity fed from the reservoir to the cooling liquid conduit of the processor stack(s).

Cooling liquid may be returned from the conduit(s) to the reservoir through a heat exchanger (e.g. a passive heat exchanger) that cools the liquid before it is returned to the reservoir. Where a heat exchanger is used it may be located remotely from the processor stacks.

The supply circuit may include one or more pumps to pump the cooling liquid from the reservoir through the conduit(s) and/or from the conduit(s) back to the reservoir.

In some embodiments, provision is made for diverting water from the conduit outlet away from the reservoir, e.g. to a drain, in order to cater, for instance, for pump failures.

In some embodiments, provision is made for selectively connecting the inlet of the conduit(s) to an alternate water (or other cooling liquid supply), e.g. a mains water supply. This might be useful in an emergency, e.g. when pumps fail or when the supply from the reservoir becomes unavailable for some other reason.

The processor stacks in the data center may be configured (e.g. with an appropriate balance between processing nodes and storage nodes) to best match the intended use(s) of the data center. Different processor stacks within the data center may be configured differently from one another. For instance, some stacks may be primarily (or entirely) populated with processing nodes, whereas others may be primarily (or entirely) populated with storage nodes.

The efficient cooling of the processor stacks means they can be arranged closely to one another in the data center and may be more densely packed than conventional rack arrangements. The limit will typically be imposed by a need to allow physical access to the processor stacks, e.g. for maintenance.

### BRIEF DESCRIPTION OF DRAWINGS

An embodiment of the present invention will now be described by way of example only with reference to the accompanying drawings, in which:

FIG. 1a is a schematic illustration of a data center processor stack according to an embodiment of the invention;

FIGS. 1b to 1g illustrate the processor stack of FIG. 1, with one or more components removed for illustrative purposes, to better show the structure and components of the stack;

FIG. 2 is an enlarged view of a section of the processor stack of FIG. 1;

FIGS. 3a and 3b schematically illustrate the manner in which a processing module is mounted in the processor stack of FIGS. 1 and 2;

FIG. 4 schematically illustrates a data center installation comprising multiple processor stacks; and

FIG. 5 is a schematic illustration of a data redundancy model that can be used in a data center in accordance with an embodiment of the invention.

### DESCRIPTION OF EMBODIMENT

### Data Processor Stack—‘CoreStalk’

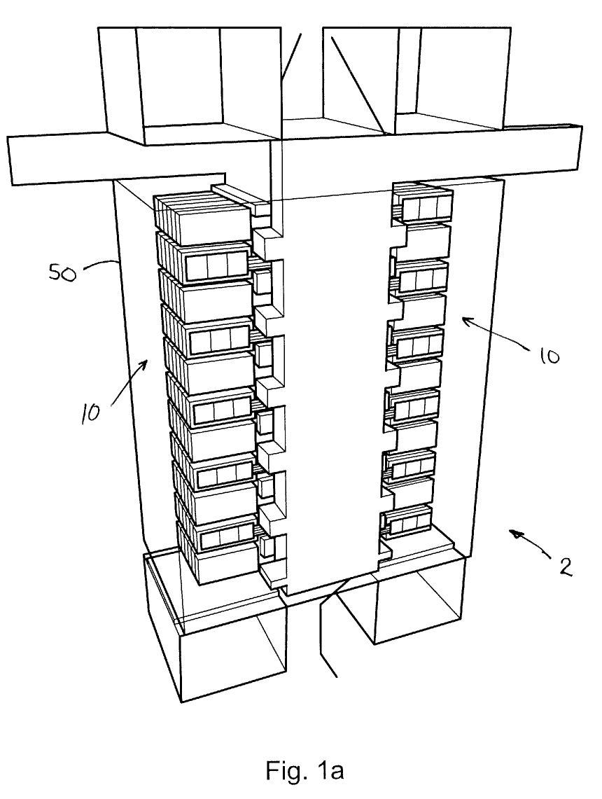

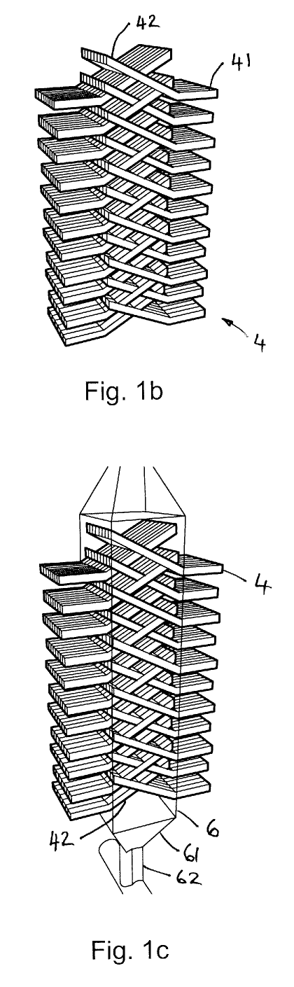

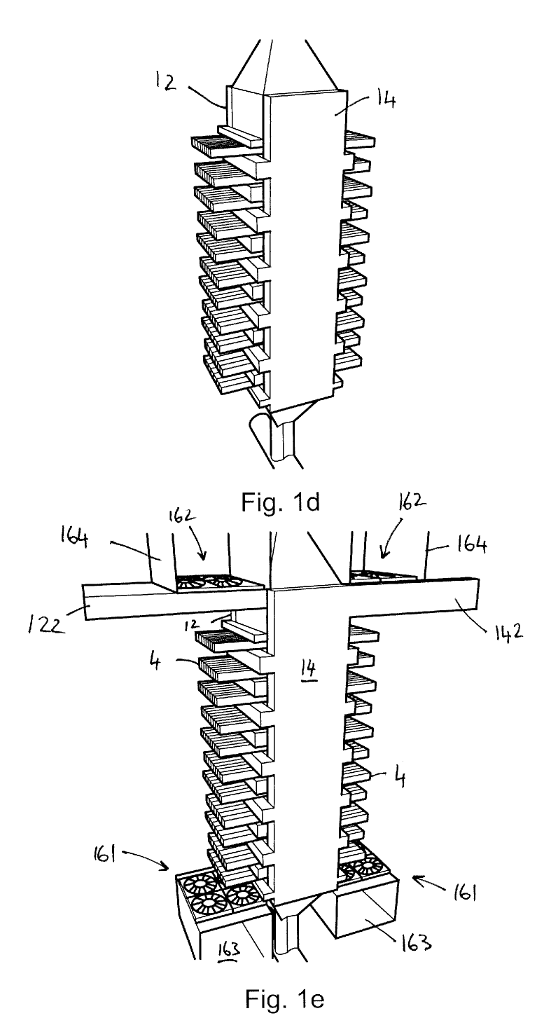

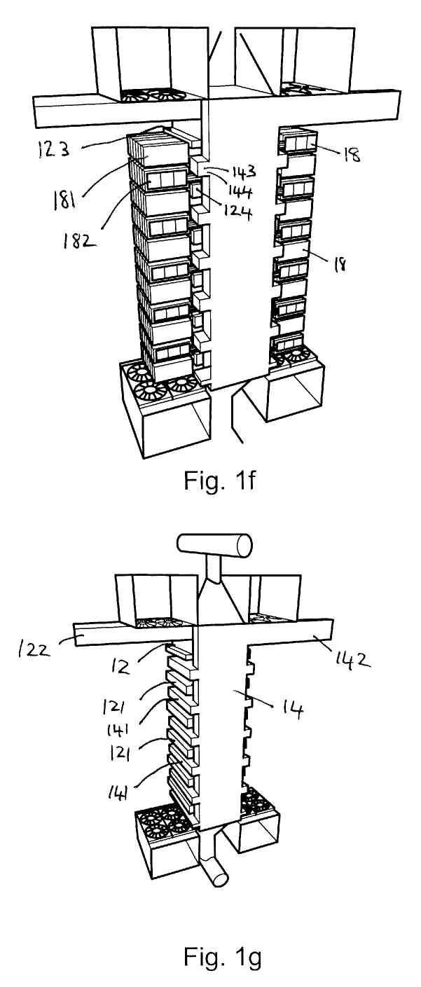

FIG. 1a illustrates a data processor stack 2, referred to as a ‘CoreStalk’ in the following, for use in a data center environment. As explained in more detail below, the stack 2 is built around a novel cooling system that uses a liquid cooling medium (in this example water) as the primary mechanism for transporting heat away from the stack 2. However, to avoid the need for intricate pipe work with a server or other mechanisms to bring the cooling water into close proximity with heat generating components (especially processors) in the stack 2, heat is conducted from these components to the cooling water by heat pipe conductors 4 (see FIG. 1b) that extend laterally from a central column 6 of cooling water (see FIG. 1c) in the stack 2 out to the components.

In more detail, and with reference to the figures, the CoreStalk concept is aimed at bringing computer processors closer to a better cooling solution, rather than the more difficult and expensive delivery of better cooling to a processor in a box. Its design is centred around a column or “Stalk” 6 of cooling liquid (e.g. water), best seen in FIG. 1c. In this example the “Stalk” 6 is 2 metres high.

The structure and components of the CoreStalk 2 will be explained in more detail with reference to FIGS. 1a to 1g.

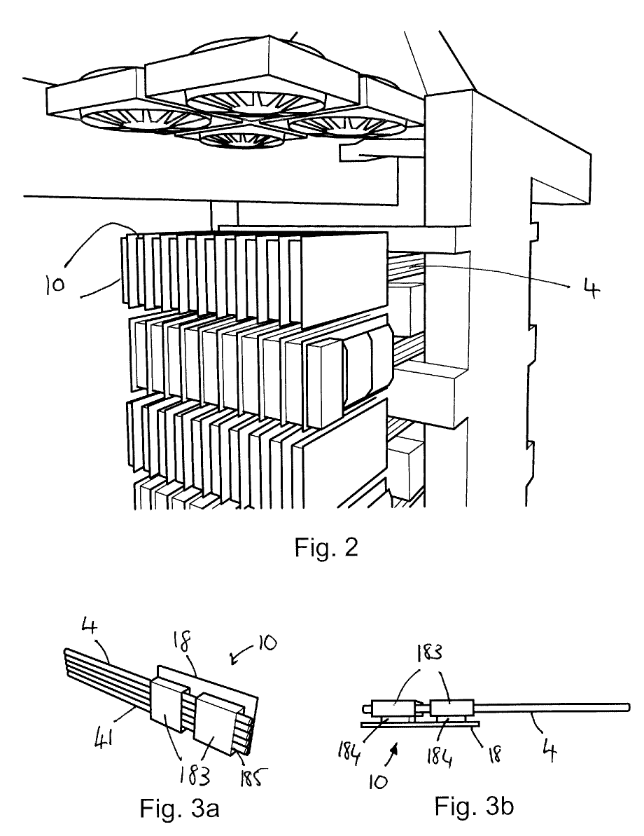

FIG. 1b shows the three-dimensional lattice array of heat pipes 4 that is at the heart of the CoreStalk 2. The heat pipes 4 extend laterally outwardly to two opposite sides of the CoreStalk and in this example are arranged in sets of 5 (see FIGS. 2 and 3). There are a total of 220 sets of heat pipes 4.

Each set of 5 heat pipes 4 defines a node 10, as discussed further below. As best seen in FIG. 1b, each heat pipe 4 is bent so that an outer portion 41 (about ⅓ of its length) extends generally horizontally, whereas an inner portion 42 rises upwardly towards and beyond the centre of the CoreStalk. This upward angulation of the inner heat pipe portions has been shown to improve the rate of heat transfer from the outer to the inner end of the pipe 4.

FIG. 1c shows the conduit defining the column or “Stalk” 6 of cooling liquid (e.g. water) in the centre of the CoreStalk 2. In this example, the conduit 6 is designed to contain a 660 litre column of water. The conduit has a tapered base 61, with an outlet 62 for the circulating cooling liquid at the bottom. Alternatively, the base may be flat and the outlet may extend laterally from a side wall of the conduit at the base (e.g. horizontally).

As can be seen, the inner ends 42 of the heat pipes 4 extend into and across substantially the full width of the conduit 6, so that a substantial portion of their length (about ½ to ⅓) is submerged in the flow of cooling liquid. A further advantage of the upward inclination of the heat pipes 4 is that a greater length of heat pipe 4 is immersed in the cooling liquid than would be possible if the pipes 4 extended horizontally across the conduit 6. This in turn provides for a greater rate of heat transfer from the pipes 4 to the cooling liquid (as a result of the increased surface area of pipe 4 that is submerged in the liquid).

FIG. 1d shows the manner in which the power supply 12 and switch fabric 14 encasements wrap around the central cooling liquid conduit 6. FIG. 1g, from which the heat pipes are omitted, also shows that manner in which power supply and switch fabric conduits extend alternately along the sides of the CoreStalk to provide power and data connections 121, 141 respectively to the nodes 10 of the CoreStalk 2 as explained in more detail further below.

In some embodiments it may be desirable to cool the power supply 12 and/or switch fabric 14 encasements and this can be done, for example, by using one or more additional heat pipes (or other heat conductors/heat transfer arrangements) (not shown), to transfer heat from one or both of these encasements to the central column of cooling liquid.

FIG. 1e shows, in addition to the components seen in FIG. 1d, banks of cooling fans 16 that are used to blow air upwardly over the nodes of the CoreStalk 2. As can be seen, there are 16 fans in total in this example, four fans 161 at the bottom and four fans 162 at the top of the Stalk on each side to which nodes are mounted (i.e. the sides to which the heat pipes 4 protrude). The lower fans 161 draw in filtered outside air from a pair of air inlet conduits 163 at the bottom of the stack and blow this air vertically upwards through the CoreStalk 2. The fans 162 at the top draw the air from the top of the Stalk 2 into air exhaust conduits 164 at the top of the stack from where the heated air is exhausted to the exterior of the building in which the CoreStalk 2 is housed.

Also seen in FIG. 1e are power and switch fabric extension arms 122, 142, which extend laterally from the top ends of the power and switch fabric encasements 12, 14, that connect to non-processor areas of the data center in which the CoreStalk 2 is installed.

FIG. 1f shows the CoreStalk with processor boards 18 (motherboards) installed at each of the 220 nodes 10. As can be seen in this figure (usefully, reference can also be made to FIG. 1g) the connection points between the motherboards 18 and the power and fabric feeds 12, 14 alternate between top and bottom on each row. For instance, for the top row of motherboards 181 the power feed 123 is at the top edge of the boards and the fabric feed 143 is at the bottom edge of the boards 181. In the second row from the top, on the other hand, the power feed 124 is at the bottom edge of the boards 182 and the fabric feed 144 is at the top edge. This simplifies the construction of the power and fabric conduits 121, 141 (see FIG. 1g) providing the feeds and also helps to minimise magnetic field-related issues that might otherwise result from running power in close proximity parallel runs to the fabric switch. To avoid the need for two differently configured motherboard designs for the alternating rows, alternate rows of motherboards 18 are oriented in opposite directions to one another.

FIG. 1a shows the CoreStalk 2 with all of its major components in place including, in addition to the components seen in FIG. 1f, a surrounding case 50. In this example the case 50 is shown to be made from a transparent or translucent material, e.g. Perspex, but embodiments of the invention are not limited to this material. The case 50 serves to protect the components of the CoreStalk 2 e.g. from impact from external objects and also provides an enclosure (preferably a closed pressure environment) to help the fans 16 maintain adequate performance.

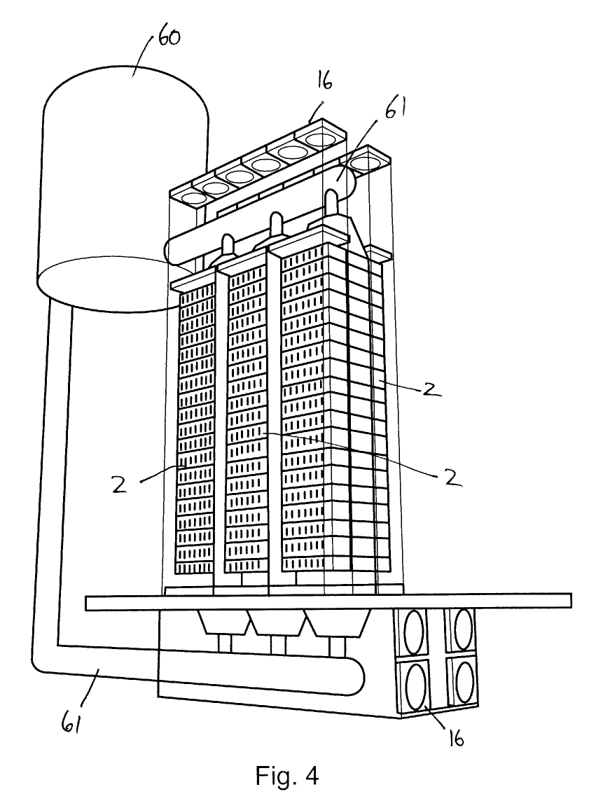

The stalk 2 may comprise a support frame (not shown) to support the vertically extending conduit 6 through which the cooling liquid flows across the ends of the heat pipe conductors 4. The cooling liquid may be pumped through the conduit 6 and/or gravity fed from a reservoir 60 (see FIG. 4). The cooling liquid is returned (e.g. pumped) to the reservoir via a passive heat exchanger (not shown) that cools the liquid.

The outer end of each heat pipe 4 can be attached to one or more heat sinks 183 which in turn are directly attached to processors 184, which in this example are mounted on specialised motherboards 18 (see FIG. 3). The combination of a motherboard 18 and processor(s) 184 is referred to in the following as a processing node or processing module.

To maximise the heat transfer from the processor(s) 184 to the stalk 6, multiple heat pipes 4 can be attached to each heat sink 183.

The maximum number of processors (with a given heat output) that can be attached to a heat pipe 4 without compromising the desired cooling effect can be determined based on three factors: i) the heat transfer capability of the individual heat pipes; ii) the number of heat pipes attached in parallel to each processor; and iii) the flow rate of cooling liquid through the column.

In this example, as best seen in FIGS. 2 and 3, the heat pipes 4 are grouped in sets of five, each heat pipe set being connected to a pair of processors 184 via their respective heat sinks 183. Each group of 5 heat pipes 4 can nominally remove 400 watts of heat, allowing a dual processor motherboard to support up to 200 watt processors or a quad processor motherboard (not shown) to support up to 100 watt processors.

Flow rate of cooling liquid through the column 6 is controlled by a variable rate valve above the column and a variable rate return pump that pumps heated cooling liquid (e.g. water) from the base of the column 6, through a heat exchanger (not shown) and back into the reservoir 60 in a closed loop.

In an advantageous enhancement to the cooling system, provision is made for the closed loop to be opened in the event of a pump failure, the flow rate through the column 6 being determined by the valve alone and the heated cooling liquid being diverted out of the cooling system as waste.

The heat exchange mechanism used to extract heat from the cooling liquid prior to its return to the reservoir may take any of a number of suitable forms. For example, liquid may be taken externally through a heat sink array for external air convection cooling. Alternatively (or additionally), it may be transferred to a traditional cooling tower system. Other conventional liquid cooling systems can be employed. In each case, however, the heat exchange preferably occurs at a location that is (thermally) isolated from the CoreStalk itself.

The combination of the heat pipes 4 and the column 6 of cooling liquid provides the primary cooling mechanism for the processing modules 10 in the CoreStalk 2. The cooling is not reliant on convection through air in the way prior art systems are. It has been determined that this primary cooling mechanism can operate to very efficiently remove as much as 80% or more of the processor heat from the system.

In this example, as can be seen clearly from the figures, the heat pipe conductors 4 also act as supports on which the processing modules 10 are mounted. More specifically, the processor heat sinks 183 comprise a series of bores 185 through which respective ones of the set of heat pipes 4 extend, thus supporting the heat sinks 183 and the motherboards 18 to which they are firmly attached. The modules 10 are supported by the internal frame of the Stalk 2, with the heat pipes 4 transferring the weight of each module 10 onto the frame. In other embodiments the heat pipes 4 need not provide all (or any) of the required support and additional support structures can be provided to supplement support provided by the heat pipes 4 or to provide all of the required support.

If the sets of heat pipes 4 alone do not provide adequate support for the module, one or more of the heat pipes 4 can be exchanged for a solid conductor. For instance, a set of five conducting elements might comprise 3 heat pipes and two solid conductors, for example arranged alternately with one another. Additional support structure may also be provided for the module if required or desired in any particular application.

This construction removes the need for a traditional “cabinet”/“racking” support structure drastically reducing the cost and impediments to airflow. It can also allow for easy and very quick removal and replacement of the processing modules 10. The module 10 slides onto the heat pipes 5 emanating from the stalk and can be adapted to snap into power and network connectors 121, 141 on the stalk.

Looking in more detail at the custom motherboards 18, the aim is to provide the smallest area possible for a given number of processors 184. The primary criteria for its design is to minimize size and power consumption while eliminating unneeded chips that would be included in a more general market server design. The unusual design criteria of being aerodynamic means that particular attention has been paid to the orientation of RAM and heatsink design to allow maximum unimpeded airflow across the board 18.

The design philosophy of only essential components means that all unnecessary chips and connectors are removed from the motherboard 18. This means no USB, Firewire, or PCI/AGP type expansion slots of any description are provided for. Even keyboard, mouse and VGA ports can dispensed with. Included ports and connectors in preferred embodiments of the motherboard are:
Single Power;
Memory sockets;
“Fabric” sockets (e.g. Infiniband of Fibre Channel) for network, storage and processor communication;
Onboard on/off switch.

The motherboard 18 may include other ports, e.g. where needed for a particular custom application. In general, however, it is preferred that all communication takes place through one or more “fabric” sockets.

Thus, the motherboard 18 can be seen in its most basic form as a conduit between electricity, processing power, storage and the network.

As already described above, around the outside of the Stalk 6 of cooling liquid a fan forced air cooling system blows air, typically at relatively low velocity, over the motherboards 18. This air cooling system removes residual heat from the processors 184 and heat from ancillary chips on the motherboard 18. The motherboards 18 may be arranged in an aerodynamic manner on the stalk to enhance this cooling effect.

Preferably a redundant fan setup is used so that the failure of any one fan 16 has no significant effect on the operation of the system.

Advantageously, provision can also be made to switch the fans 16 to a ‘high’ velocity mode (i.e. a faster speed of operation in which they blow air over the motherboards at a higher flow rate), useful for example to enable continued operation of the CoreStalk 2 (albeit with less efficient cooling) in the event of failure of the liquid cooling system.

Waste air is preferably funnelled outside of the data center instead of kept inside and air-conditioned. Intake air is also preferably externally derived and, depending on geographic region, no air conditioning of this intake air may be required, offering further energy savings over conventional data center cooling systems. Filtration of the externally derived air may be desirable, irrespective of whether it is cooled or not.

In this example, as noted above, each stalk 2 has 220 leaf nodes where a motherboard 18 (processing module/node), hard disk drive (storage module/node), or a fabric switch (switch node) can be installed. However, the concepts disclosed herein are applicable to other configurations.

Storage nodes are preferably based on Industry Standard 3.5″ and 2.5″ Hard drives and are preferably easily interchangeable. They can be mounted on the heat pipe conductors 4 in a similar manner to the mounting of the processing modules 10 discussed above. Although disk drives do not typically generate as much heat as processors, the heat pipes 4 can usefully conduct heat away from the storage modules.

Processing Nodes (modules) 10, as noted above, are customized motherboards 18 that in this example comprise 2 multicore CPUs. For each motherboard 8 or more traditional DDR2 memory sockets are available, addressing up to 32 Gb or more of memory per motherboard. In other examples, any of a number of available memory types supported by the motherboard may be used, e.g. DDR, DDR4, etc.

Thus the 220 leaf nodes allow for a maximum of 440 processors, with in excess of 7Tb of RAM, or 220 groups of 3×3.5″ or 5×2.5″ Hard drives to be installed on any single CoreStalk. In other examples, it is envisaged that 4 processors will be provided per processing node, giving a possible total of 880 processors.

As will be appreciated, the CoreStalk 2 of this example offers significant benefits over conventional rack-based systems for data centers. In particular, although each CoreStalk 2 is designed to occupy the same floor space as a regular 19″ 42 RU rack, its unique cooling system means that processor density can be much higher (e.g. 200% to 600% higher) in the CoreStalk than in conventional systems. Moreover, the efficiency of the cooling system means there is practically little or no thermal limit on the number of CoreStalks that can be mounted side-by-side.

The server fabric 14 (or communication fabric) in this example is mounted on the side of the stalk 6 and can be selected from any of a number of available standards, for example: 12× Infiniband, 4× Infiniband, 10 Gb Ethernet, Fibre Channel etc. Output converters in the server fabric may also allow converted output to one or more of these standards.

CoreStalks 2 can be customized for application purposes. For instances companies interested in massive grid computing may elect to fill out many CoreStalks with the maximum 440 processors per stalk, and only use Storage Nodes on a few of it's Stalks. At the other extreme companies interested in maximizing storage for high definition video steaming may elect to populate most of its stalks with as many Storage Nodes as possible.

### Data Centers—‘StalkCenter’

In practice, multiple CoreStalks 2 will be installed and networked together to create a data center. As shown schematically in FIG. 4, which illustrates three CoreStalks arranged side-by-side, in data center environments employing multiple CoreStalks 2 some components of the cooling system, in particular the cooling liquid reservoir 60 and associated pipework 61, can be shared by multiple CoreStalks 2.

A data center consisting of CoreStalks 2 (referred to in the following as a StalkCenter) can be purpose designed for a set number of stalks and power requirement. The StalkCenter is preferably designed to cater for the unique characteristics of the CoreStalk and allows deployment into areas not commonly targeted or available to regular data centers (for example small footprint locations and areas a significant distance from a customer base).

Due to the very dense processor counts of a single CoreStalk 2, a StalkCenter's size will typically be limited by the power grid availability of the physical location, and it's proximity to high bandwidth Internet connection.

From an electrical power perspective a StalkCenter can be an entirely DC environment. AC to DC conversion is preferably performed by large scale external units (where needed) so there is negligible (preferably zero) thermal intrusion into the data center processing area.

The StalkCenter preferably includes redundant UPS and PSUs to power the CoreStalks.

From a networking perspective a standard approach can be used in which nodes are connected to a redundant array of network switches and routers, for example via 12× Infiniband, 4× Infiniband, 10 Gb Ethernet, Fibre Channel, etc. Multiple network providers and entry points are preferably utilized both for redundancy and to support the massive bandwidth requirements a fully utilized StalkCenter can generate.

The physical placement of all UPS, PSU and network devices is preferably engineered to isolate them from the main processing area and in an environment where adequate conventional ventilation and air conditioning can be provided.

Conveniently, a multistory building can be used to reduce horizontal sprawl.

A small Infrastructure room may also be provided with a single traditional rack of equipment for physical backup systems and interfaces (i.e. CDROM drives, keyboards, mice, video consoles etc) that are absent from CoreStalk servers. These allow server imaging, installation and troubleshooting to be performed across the network for CoreStalk nodes.

Though the Processor and Storage nodes in any one CoreStalk 2 have limited variations, multiple CoreStalks in StalkCenters can be configured in a variety of ways. For instance backups can be performed via “backup Stalks” configured to Snapshot appropriate nodes of other stalks. In currently envisaged applications for StalkCenters, this backup mechanism is not for data security as such, but exists for the purpose of archival retrieval as required. Transfer of backed up data to physical media via traditional tape based hardware is also preferably provided for.

The data storage and processing systems implemented in the StalkCenter are preferably completely virtualized. This can allow for the failure of a single node without any effect on the operation of the Stalk as a whole. More generally, it can be noted that the CoreStalk/StalkCenter hardware is a particularly suitable structure for the operation of virtualized server solutions, allowing amongst other things very rapid virtual host establishment.

### Data Redundancy & Multiple Data Centers—‘StalkNet’

StalkCenters are preferably operated in a manner that provides multi-point redundancy along with immunity (at least to some extent) from local, national, or continental events. The approach adopted in StalkCenters recognises that fundamentally it is data that is required to be redundant and highly accessible, not servers or infrastructure.

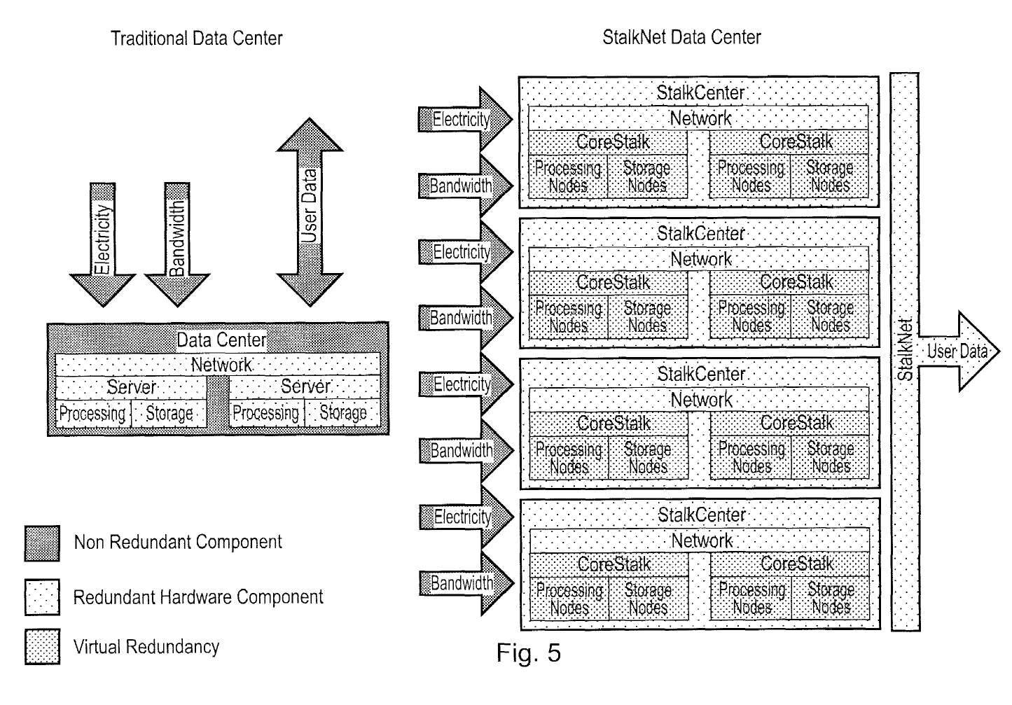

Redundancy in the StalkCenter system exists on 2 levels (as illustrated schematically in FIG. 5):
The first is Virtualization within the StalkCenter
The second is data replication across StalkCenters

### First Level Redundancy—Virtualization

In preferred implementations of StalkCenters, a single node on a CoreStalk has no redundancy (and in practice would not be deployed). An entire CoreStalk however can have redundancy via virtualization of its servers. If a Storage Node or Processing Node goes down, the virtualization software shifts the load across to other nodes in the StalkCenter.

As a StalkCenter has superior cooling that is not limited by physical air-conditioning infrastructure, maximizing the use of processors and storage via virtualization is much more efficient than traditional clustered solutions. This is in sharp contrast to other data center designs that aim to minimize underutilized processing power to save on electricity costs for cooling.

Thus, adopting this approach, StalkCenters need not have separate backup servers, NAS/SAN arrays or backup power generators. These items, common in conventional data centers, add huge capital and maintenance costs to a data center and are as inherently unreliable as the server hardware components themselves.

### Second Level Redundancy—Replication

The second mechanism is data replication across multiple StalkCenters, referred to in the following as a StalkNet.

A StalkNet preferably employs replication points at three or more StalkCenters in diverse geographic locations. When data is written to the StalkNet identical copies of the data are delivered to all of the replication points. Adopting this approach, in the event of power loss to a StalkCenter or natural disaster the data can be recovered from the other replication points.

Preferably, on failure of a StalkCenter that is part of a StalkNet two events are triggered. The first is to locate a replacement StalkCenter in a separate location that can take the place in the StalkNet of the failed StalkCenter. The second event is the streaming of data from the remaining nodes to rebuild nodes of the failed StalkCenter on the replacement StalkCenter.

The StalkNet approach can also be used to give faster and more reliable access to data, even absent a failure of StalkCenter. In particular, read events from the customer can be streamed from the closest or fastest StalkCenter available. Alternatively, data can be simultaneously streamed from multiple StalkCenters maximizing speed of transmission. This provides for high speed data delivery and can circumvent Internet bottlenecks and outages; Internet congestion in one area does not affect the speedy delivery of data to the customer.

By providing replication points at appropriate remote geographical locations, it also becomes possible e.g. to serve data to branch offices and travelling users at the same high speed experienced by users in a main office, the particular StalkCenters used in the StalkNet being selected based on branch office locations, likely travel destinations etc.

1. A cooling system for electronic equipment comprising a plurality of heat producing electronic components, the cooling system comprising:
a conduit carrying a cooling liquid; and
a plurality of elongate heat conducting elements extending outwardly from the conduit;
an inner end portion of each heat conducting element being in thermal contact with cooling liquid in the conduit and an outer end portion of each heat conducting element being adapted for conductive thermal contact with at least one heat producing electronic component.

2. A cooling system according to claim 1, wherein the cooling liquid is water.

3. A cooling system according to claim 1, wherein the cooling liquid flows through the conduit past or across the inner end portions of the heat conductors.

4. A cooling system according to claim 1, wherein the inner end portions of the heat conducting elements extend inside the conduit so that they are immersed in the cooling liquid.

5. A cooling system according to claim 4, wherein the inner end portions of the heat conducting elements extend across substantially the whole width of the conduit

6. A cooling system according to claim 1, wherein inner ends of the heat conducting elements are thermally connected to heat sinks over which the cooling liquid flows inside the conduit, the heat sinks having a larger surface area than the heat elements they are connected to.

7. A cooling system according to claim 1, wherein the conduit is elongate and is oriented to be vertical with the heat conductors extending generally laterally therefrom.

8. A cooling system according to claim 1, wherein the heat conducting elements slope upwards towards their inner ends.

9. A cooling system according to claim 1, wherein the heat conductors protrude from more than one side of the conduit.

10. A cooling system according to claim 1, wherein a plurality of heat conductors protrude from one or more sides of the conduit, the conductors on any one side of the conduit being spaced from one another along the length and/or width of the conduit.

11. A cooling system according to claim 1, wherein there are 200 or more heat conducting elements protruding from the conduit.

12. A cooling system according to claim 1, wherein one or more of the heat conductors are adapted to each be in thermal contact with more than one heat producing electronic component.

13. A cooling system according to claim 1, wherein two or more of the heat conducting elements are adapted to be in thermal contact with the same heat producing component.

14. A cooling system according to claim 1, wherein the heat conducting elements are in conductive thermal contact with the heat producing components via physical contact with a heat sink that is in physical contact with the heat producing component.

15. A cooling system according to claim 1, wherein the heat conducting elements are elongate rods.

16. A cooling system according to claim 1, wherein the heat conducting elements are heat pipes.

17. A cooling system according to claim 1, wherein at least some of the heat conducting elements are adapted to provide a physical support for the heat producing electronic components.

18. A cooling system according to claim 1, wherein the electronic equipment for which the cooling system is provided is data center equipment.

19. A cooling system according to claim 1, wherein the heat producing components that are cooled comprise semiconductor components.

20. A cooling system according to claim 1, wherein the heat producing components that are cooled comprise magnetic, optical or combination storage devices.

21. Electronic apparatus comprising:
a plurality of heat producing electronic components; and
a cooling system for the electronic components, the cooling system comprising:
a conduit carrying a cooling liquid; and
a plurality of elongate heat conducting elements extending outwardly from the conduit;
an inner end portion of each heat conducting element being in thermal contact with cooling liquid in the conduit and an outer end portion of each heat conducting element being adapted for conductive thermal contact with at least one heat producing electronic component as set forth in the first aspect above.

22. A data center processor stack comprising:
a plurality of heat producing electronic components;
a support structure for the electronic components; and
a cooling system for the electronic components, the cooling system comprising:
i. a conduit carrying a cooling liquid; and
ii. a plurality of elongate heat conducting elements extending outwardly from the conduit;
iii. an inner end portion of each heat conducting element being in thermal contact with cooling liquid in the conduit and an outer end portion of each heat conducting element being adapted for conductive thermal contact with at least one of said electronic components.

23. A data center processor stack according to claim 22, wherein the heat producing electronic components are processors, storage units, switches or a combination of any two more of these types of component.

24. A data center processor stack according to claim 22, wherein the heat conducting elements are heat pipes.

25. A data center processor stack according to claim 22, wherein the heat conducting elements serve as part of the support structure for the processors.

26. A data center processor stack according to claim 22, wherein the electronic components are selectively detachable from the support structure.

27. A data center processor stack according to claim 22, comprising a plurality of nodes where a modular component can be installed, the modular component comprising one or more of said heat producing electronic components.

28. A data center processor stack according to claim 22, comprising a fan for generating a flow of air over the heat producing electronic components.

29. A data center comprising a plurality of data center processor stacks, each data center processor stack comprising:
a plurality of heat producing electronic components;
a support structure for the electronic components; and
a cooling system for the electronic components, the cooling system comprising:
i. a conduit carrying a cooling liquid; and
ii. a plurality of elongate heat conducting elements extending outwardly from the conduit;
iii. an inner end portion of each heat conducting element being in thermal contact with cooling liquid in the conduit and an outer end portion of each heat conducting element being adapted for conductive thermal contact with at least one of said electronic components.

30. A data center according to claim 29, wherein the processor stacks are connected to a common data network.

31. A data center according to claim 30, wherein the data network is connected to the Internet.

32. A data center according to claim 29, wherein the processor stacks have a shared power supply.

33. A data center according to claim 32, wherein the power supply is located away from the processor stacks in an isolated area.

34. A data center according to claim 29, wherein the cooling systems of a plurality of the processor stacks in the data center have a shared cooling liquid supply circuit.

35. A data center according to claim 34, wherein the cooling liquid supply circuit includes a cooling liquid reservoir from which cooling liquid is fed to the conduits of the cooling systems, the cooling liquid supply circuit further comprising a heat exchanger via which the cooling liquid is returned from the conduits to the reservoir.

36. A data center according to claim 35, wherein the heat exchanger is located remotely from the processor stacks.

37. A data center according to claim 35, wherein the cooling liquid supply circuit comprises one or more valves for diverting cooling liquid from a conduit outlet away from the reservoir.

38. A data center according to claim 35, comprising an alternate cooling liquid supply and one or more valves for connecting the alternate supply to one or more of the conduits.
